(19) United States
(12) Patent Application Publication
(10) Pub. No.: US 2016/0351712 A1
(43) Pub. Date: Dec. 1, 2016

(54) METHOD FOR INCREASING STRESS IN THE CHANNEL REGION OF FIN FIELD EFFECT TRANSISTOR

(71) Applicant: UNITED MICROELECTRONICS CORP., Hsin-Chu City (TW)

(72) Inventors: Huai-Tzu Chiang, Tainan City (TW); Sheng-Hao Lin, Hsinchu County (TW); Hsin-Yu Chen, Nantou County (TW); Hao-Ming Lee, Taichung City (TW)

(21) Appl. No.: 14/754,708

(22) Filed: Jun. 30, 2015

(30) Foreign Application Priority Data
May 25, 2015 (TW) 104116614

(51) Int. Cl. H01L 29/78; H01L 29/423; H01L 21/3105; H01L 29/49; H01L 21/324; H01L 21/28; H01L 29/40; H01L 29/66

(52) U.S. Cl. CPC H01L 29/7845; H01L 29/401; H01L 29/42372; H01L 29/42364; H01L 29/66545; H01L 29/4966; H01L 21/324; H01L 21/28088; H01L 21/31051

(57) ABSTRACT

A method for fabricating semiconductor device is disclosed. The method includes the steps of: providing a substrate; forming a gate structure on the substrate; forming an interlayer dielectric (ILD) layer around the gate structure; removing the gate structure to form a recess; forming a stress layer in the recess, wherein the stress layer comprises metal; and forming a work function layer on the stress layer.

### BACKGROUND OF THE INVENTION

1. Field of the Invention

The invention relates to a method for fabricating fin field effect transistor (FinFET), and more particularly, to a method of increasing stress in the channel region of the FinFET.

2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the FinFET can be controlled by adjusting the work function of the gate.

Typically, epitaxial layer composed of silicon germanium is formed on the source/drain region adjacent two sides of the gate structure in planar MOS transistors. Nevertheless, as this technique is brought to FinFET devices, the growth of epitaxial layer could only facilitate the stress along source/drain region direction but unable to increase the stress along height direction of fin-shaped structure. Hence, how to improve the current FinFET architecture for resolving this issue has become an important task in this field.

### SUMMARY OF THE INVENTION

According to a preferred embodiment of the present invention, a method for fabricating semiconductor device is disclosed. The method includes the steps of: providing a substrate; forming a gate structure on the substrate; forming an interlayer dielectric (ILD) layer around the gate structure; removing the gate structure to form a recess; forming a stress layer in the recess, wherein the stress layer comprises metal; and forming a work function layer on the stress layer.

According to another aspect of the present invention, a method for fabricating semiconductor device is disclosed. The method includes the steps of: providing a substrate; forming agate structure on the substrate; forming an interlayer dielectric (ILD) layer on the gate structure; performing a first anneal process; removing the gate structure to form a recess.

According to another aspect of the present invention, a semiconductor device is disclosed. The semiconductor device includes a substrate; and a gate structure on the substrate, in which the gate structure includes an interfacial layer, a stress layer on the interfacial layer, and a work function layer on the stress layer. Preferably, the stress layer is composed of metal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating semiconductor device according to a preferred embodiment of the present invention.

FIG. 5 illustrates a three-dimensional view of a semiconductor device according to a preferred embodiment of the present invention.

FIG. 6 illustrates a cross-sectional view of FIG. 5 along sectional line BB′.

### DETAILED DESCRIPTION

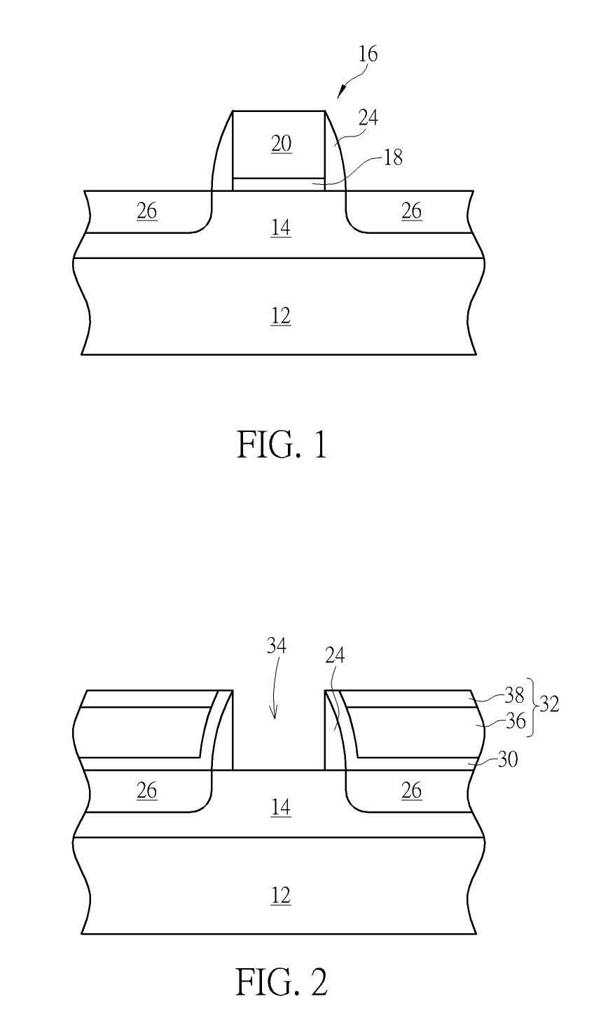

Referring to FIGS. 1-4, FIGS. 1-4 illustrate a method for fabricating semiconductor device according to a preferred embodiment of the present invention. As shown in FIG. 1, a substrate 12, such as a silicon substrate or silicon-on-insulator (SOI) substrate is provided, and a transistor region, such as NMOS region is defined on the substrate 12. At least a fin-shaped structure 14 and an insulating layer (not shown) are formed on the substrate 12, in which the bottom of the fin-shapes structure 14 is preferably enclosed by the insulating layer, such as silicon oxide to form a shallow trench isolation (STI), and a dummy gate or gate structure 16 is formed on part of the fin-shaped structure 14.

The formation of the fin-shaped structure 14 could be accomplished by first forming a patterned mask (now shown) on the substrate, 12, and an etching process is performed to transfer the pattern of the patterned mask to the substrate 12. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form an insulating layer surrounding the bottom of the fin-shaped structure 14. Alternatively, the formation of the fin-shaped structure 14 could be accomplished by first forming a patterned hard mask (not shown) on the substrate 12, and then performing an epitaxial process on the exposed substrate 12 through the patterned hard mask to grow a semiconductor layer. This semiconductor layer could then be used as the corresponding fin-shaped structure 14, the patterned hard mask could be removed selectively or retained, and deposition, CMP, and then etching back could be used to form a STI surrounding the bottom of the fin-shaped structure 14. In another fashion, if the substrate 12 were a SOI substrate, a patterned mask could be used to etch a semiconductor layer on the substrate until reaching a bottom oxide layer underneath the semiconductor layer to form the corresponding fin-shaped structure. If this means is chosen the aforementioned steps for fabricating the STI could be eliminated.

The formation of the gate structure 16 could be accomplished by a gate first process, a high-k first approach from gate last process, or a high-k last approach from gate last process. Since this embodiment pertains to a high-k last approach, a gate structure 16 composed of interfacial layer 18 and polysilicon gate 20 is formed on the fin-shaped structure 14, a spacer 24 is formed on sidewalls of the gate structure 16, a source/drain region 26 and/or epitaxial layer is formed in the fin-shaped structure 14 and/or substrate 12 adjacent to two sides of the spacer 24, and a silicide layer (not shown) is formed on the surface of the source/drain region 26 and/or epitaxial layer.

Referring to FIGS. 2-3, FIG. 2 illustrate a perspective view of the method of fabricating semiconductor device following FIG. 1 and FIG. 3 is a flow chart showing steps conducted for forming interlayer dielectric (ILD) 32 after the formation of source/drain region 26. As shown in FIGS. 2-3, a contact etch stop layer (CESL) 30 is first deposited to cover the gate structure 16 in step 102, a flowable chemical vapor deposition (FCVD) process is conducted to form a silicon oxide layer 36 on the CESL 30 in step 104, a cap oxide layer 38 is formed on the silicon oxide layer 36, and a planarizing process such as CMP is conducted in step 108 to remove part of the ILD layer 32 (including cap oxide layer 38 and silicon oxide layer 36) and part of the CESL 30 for exposing the gate structure 16 surface so that the top surface of the polysilicon gate 20 of gate structure is even with the top surface of ILD layer 32. Next, a SiCoNi clean process is conducted in step 110 to remove excessive native oxides, and a dry etching or wet etching process is selectively conducted in step 112 by using ammonium hydroxide (NH₄OH) or tetramethylammonium hydroxide (TMAH) to remove the polysilicon gate 20 and interfacial layer 18 for forming a recess 34 in the ILD layer 32.

In this embodiment, the ILD layer 32 could be composed of a silicon oxide layer 36 and a cap oxide layer 38, and an anneal process could be conducted before or after the formation of CESL 30 and ILD layer 32 to increase the tensile stress of the CESL 30 and ILD layer 32. Specifically, it would be desirable to conduct an anneal process between step 102 and step 104, an anneal process between step 104 and step 106, an anneal process between step 106 and step 108, an anneal process between step 108 and step 110, or an anneal process between step 110 and step 112, which are all within the scope of the present invention. According to a preferred embodiment of the present invention, the anneal process conducted between step 102 and step 104 could be used to increase the tensile stress along width direction of fin-shaped structure 14 (or the extending direction of gate structure 16), whereas the anneal process conducted between step 104 and step 106, the anneal process conducted between step 106 and step 108, the anneal process conducted between step 108 and step 110, and the anneal process conducted between step 110 and step 112 could be used to increase the tensile stress along height direction of fin-shaped structure 14.

It should be noted that even though only one of the aforementioned five timings from step 102 to step 112 is selected to conduct an anneal process, it would also be desirable to conduct anneal processes on CESL 30 and ILD layer 32 in any two of the aforementioned timings or time slots, in any three of the aforementioned time slots, in any four of the aforementioned time slots, or even in all five of the aforementioned time slots for increasing tensile stress of the device. Preferably, each of the anneal process conducted includes a laser anneal process, and the operation temperature of each anneal process is preferably between 1000° C. to 1300° C.

Next, as shown in FIG. 4, another interfacial layer 40 is formed in the recess 34 above the fin-shaped structure 14, or if the aforementioned interfacial layer 18 were not removed completely during the removal of polysilicon gate 20, it would be desirable to first remove the remaining interfacial layer 18 and then form another interfacial layer 40 in the recess 34 to ensure the quality of the interfacial layer. A high-k dielectric layer 42, a stress layer 44, a work function metal layer 46, and a low resistance metal layer 48 are then sequentially formed into the recess 34, and a planarizing process such as CMP is conducted to remove part of the low resistance metal layer 48, part of the work function metal layer 46, part of the stress layer 44, and part of the high-k dielectric layer 42 to form a metal gate.

According to an embodiment of the present invention, it would be desirable to selectively deposit an amorphous silicon layer (not shown) on the ILD layer 32 and stress layer 44 after stress layer 44 is formed, and a rapid thermal anneal process is conducted to re-build molecular structure of the material layers, and then remove the amorphous silicon layer completely before forming the work function metal layer 46 on the stress layer 44, which is also within the scope of the present invention.

In this embodiment, the stress layer 44 is selected from the group consisting of Ti, TiN, Ta, and TaN, and most preferably TiN. Moreover, the stress layer 44 is preferably a compressive stress layer.

The high-k dielectric layer 42 could be a single-layer or a multi-layer structure containing metal oxide layer such as rare earth metal oxide, in which the dielectric constant of the high-k dielectric layer 42 is substantially greater than 20. For example, the high-k dielectric layer 42 could be selected from the group consisting of hafnium oxide (HfO₂), hafnium silicon oxide (HfSiO), hafnium silicon oxynitride (HfSiON), aluminum oxide (AlO), lanthanum oxide (La₂O₃), lanthanum aluminum oxide (LaAlO), tantalum oxide, Ta₂O₃, zirconium oxide (ZrO₂), zirconium silicon oxide (ZrSiO), hafnium zirconium oxide (HfZrO), strontium bismuth tantalite (SrBi₂Ta₂O₉, SBT), lead zirconate titanate (PbZrₓTi₁₋ₓO₃, PZT), and barium strontium titanate (BaₓSr₁₋ₓTiO₃, BST).

In this embodiment, the work function metal layer 46 is formed for tuning the work function of the later formed metal gates to be appropriate in an NMOS or a PMOS. For an NMOS transistor, the work function metal layer 46 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 46 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 46 and the low resistance metal layer 48, in which the material of the barrier layer may include titanium (Ti), titanium nitride (TiN), tantalum (Ta) or tantalum nitride (TaN). Furthermore, the material of the low-resistance metal layer 48 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

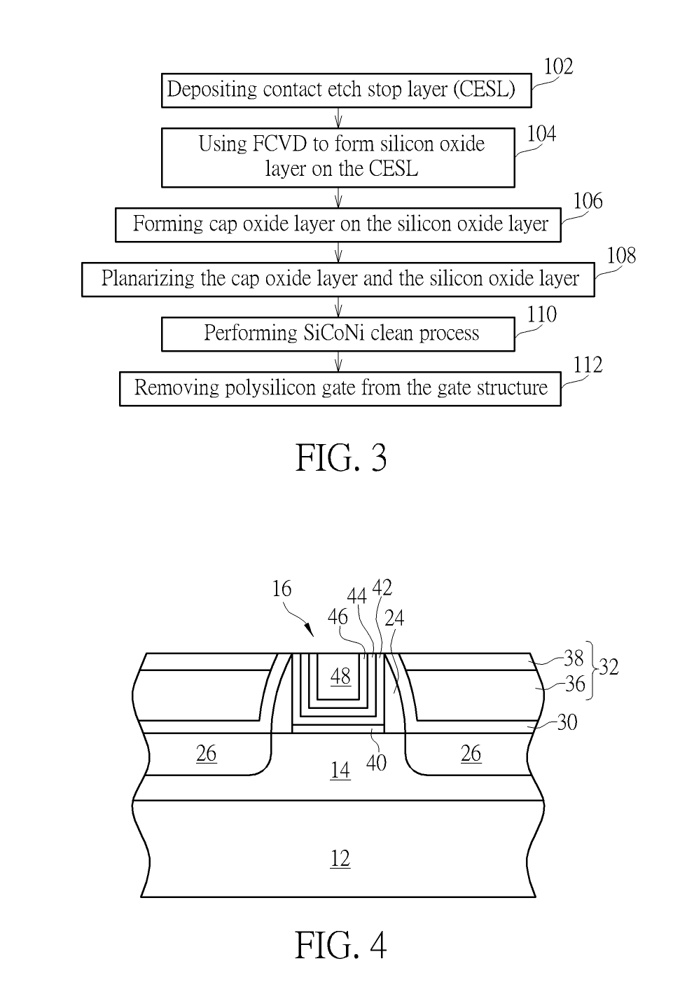

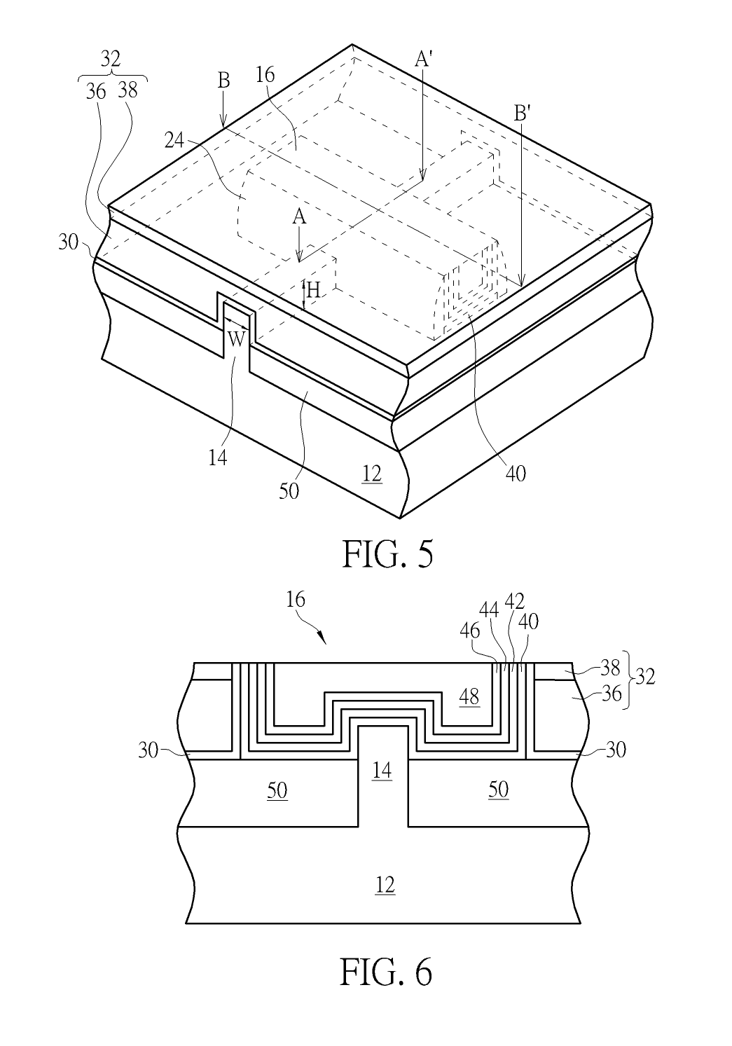

Referring to FIGS. 4-6, FIG. 5 illustrates a three-dimensional view of a semiconductor device according to a preferred embodiment of the present invention, FIG. 4 illustrates a cross-sectional view of FIG. 5 along sectional line AA′, and FIG. 6 illustrates a cross-sectional view of FIG. 5 along sectional line BB′. As shown in the figures, the semiconductor device of the present invention preferably includes a substrate 12, a fin-shaped structure 14 disposed on the substrate 12, a spacer 24 disposed around the gate structure 16, and a source/drain region 26 disposed in the fin-shaped structure 14 adjacent to two sides of the spacer 24. The gate structure 16 includes an interfacial layer 40, a high-k dielectric layer 42 atop the interfacial layer 40, a stress layer 44 on the high-k dielectric layer 42, a work function metal layer 46 on the stress layer 44, and a low resistance metal layer 48 on the work function metal layer 46.

In this embodiment, the high-k dielectric layer 42, stress layer 44, and work function metal layer 46 are all U-shaped. The stress layer 44 is selected from the group consisting of Ti, TiN, Ta, and TaN, and most preferably TiN. Moreover, the stress layer 44 is preferably a compressive stress layer.

Overall, the present invention discloses a method of increasing tensile stress in the channel region of NMOS FinFET device, in which the method could be primarily achieved by two approaches. According to a first embodiment of the present invention, it would be desirable to perform an anneal process after forming CESL but before depositing ILD layer, after depositing ILD layer but before planarizing ILD layer, or after planarizing ILD layer but before removing dummy gate. Preferably, the anneal process could be conducted in any one or any combination from the aforementioned timings to increase the tensile stress of NMOS transistor along width direction (such as along the width W in FIG. 5) of fin-shaped structure or increase the tensile stress along height direction (such as along the height H in FIG. 5) of fin-shaped structure. According to a second embodiment of the present invention, it would be desirable to form a compressive stress layer composed of metal material on the high-k dielectric layer after dummy gate is removed. This compressive stress layer is preferably used for increasing the tensile stress of NMOS transistor along height direction H of fin-shaped structure as shown in FIG. 5.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a semiconductor device, comprising:
providing a substrate and a fin-shaped structure on the substrate;
forming a gate structure on the substrate;
forming an interlayer dielectric (ILD) layer around the gate structure;
removing the gate structure to form a recess;
forming a stress layer in the recess to increase a tensile stress of the semiconductor device along a height direction of the fin-shaped structure, wherein the stress layer comprises a metal; and
forming a work function layer on the stress layer.

2. The method of claim 1, further comprising:
forming an interfacial layer in the recess;
forming a high-k dielectric layer on the interfacial layer; and
forming the stress layer on the high-k dielectric layer.

3. The method of claim 1, wherein the stress layer comprises a compressive stress layer.

4. The method of claim 1, wherein the stress layer comprises TiN.

5. The method of claim 1, further comprising forming a low resistance metal layer on the work function layer.

6. The method of claim 1, wherein the semiconductor device comprises a NMOS transistor.

7. A method for fabricating semiconductor device, comprising:
providing a substrate;
forming a gate structure on the substrate;
forming an interlayer dielectric (ILD) layer on the gate structure;
performing a first anneal process; and
removing the gate structure to form a recess.

8. The method of claim 7, further comprising performing a planarizing process to remove part of the ILD layer before performing the first anneal process.

9. The method of claim 7, further comprising performing a planarizing process to remove part of the ILD layer after performing the first anneal process.

10. The method of claim 7, further comprising:
forming a contact etch stop layer (CESL) on the substrate and the gate structure;
performing a second anneal process;
forming the ILD layer on the CESL; and
performing the first anneal process.

11. A semiconductor device, comprising:
a substrate;
a gate structure on the substrate, wherein the gate structure comprises:
an interfacial layer;
a stress layer on the interfacial layer, wherein the stress layer comprises metal; and
a work function layer on the stress layer.

12. The semiconductor device of claim 11, further comprising:
a high-k dielectric layer on the interfacial layer; and
the stress layer on the high-k dielectric layer.

13. The semiconductor device of claim 11, wherein the stress layer comprises a compressive stress layer.

14. The semiconductor device of claim 11, wherein the stress layer comprises TiN.

15. The semiconductor device of claim 11, wherein the stress layer is U-shaped.

16. The semiconductor device of claim 11, wherein the semiconductor device comprises a NMOS transistor.
